(19) United States
(12) Patent Application Publication
(10) Pub. No.: US 2023/0154997 A1
(43) Pub. Date: May 18, 2023

(54) SEMICONDUCTOR SUBSTRATE AND ELECTRICAL INSPECTION METHOD

(71) Applicant: CANON KABUSHIKI KAISHA, Tokyo (JP)

(72) Inventors: Masanori Shibata, Tokyo (JP); Makoto Takagi, Kanagawa (JP)

(21) Appl. No.: 17/979,849

(22) Filed: Nov. 3, 2022

(30) Foreign Application Priority Data
Nov. 12, 2021 (JP) 2021-184682

(51) Int. Cl. H01L 29/43; H01L 29/423; H01L 29/417; G01R 31/28

(52) U.S. Cl. CPC H01L 29/43; H01L 29/423; H01L 29/417; G01R 31/2831

(57) ABSTRACT

A semiconductor substrate has an internal circuit, a plurality of first pads electrically connected to the internal circuit, and one or a plurality of second pads that have a surface hardness lower than that of the plurality of first pads and are not electrically connected to the internal circuit.

### BACKGROUND OF THE INVENTION

### Field of the Invention

The present invention relates to a semiconductor substrate and an electrical inspection method.

### Description of the Related Art

Japanese Patent Application Laid-open No. 2021-17054 describes increasing a surface hardness of an electrode pad in order to prevent a mark of an electrical inspection needle (a needle used for electrical inspection) from being left on the pad (electrode pad) that is electrically connected to an external substrate when used.

However, there is also a problem in preventing a needle mark of the electrical inspection needle from being left on the pad when electrical inspection is performed using the electrode pad having a high surface hardness as in Japanese Patent Application Laid-open No. 2021-17054. Specifically, there arises a problem that, in a case in which a defect of a semiconductor substrate is confirmed in the electrical inspection, it is difficult to determine whether the defect was caused by a contact failure between the needle mark and the pad or by a defect inside the semiconductor substrate.

### SUMMARY OF THE INVENTION

Thus, an object of the disclosure of the present technique is to provide a technique of inhibiting a needle mark from being left on a specific pad of a semiconductor substrate during electrical inspection and making it easier to determine a cause of a defect during the electrical inspection.

An aspect of the present technique is a semiconductor substrate including: an internal circuit; a plurality of first pads electrically connected to the internal circuit; and one or a plurality of second pads that have a surface hardness lower than that of the plurality of first pads and are not electrically connected to the internal circuit.

An aspect of the present technique is a semiconductor substrate electrically connected to an external substrate, the semiconductor substrate including: an internal circuit that is a circuit to which a signal is input from the external substrate or a circuit that outputs a signal to the external substrate; a plurality of first pads electrically connecting the internal circuit to the external substrate; and one or a plurality of second pads that have a surface hardness lower than that of the plurality of first pads and do not electrically connect the internal circuit to the external substrate.

An aspect of the present technique is an electrical inspection method including: preparing a semiconductor substrate including an internal circuit, a plurality of first pads electrically connected to the internal circuit, and one or a plurality of second pads not electrically connected to the internal circuit; preparing an inspection substrate to which a plurality of inspection needles are connected; and contacting the plurality of inspection needles with the plurality of first pads and the one or plurality of second pads, wherein the plurality of first pads have a surface hardness higher than a hardness of a plurality of first inspection needles that are some of the plurality of inspection needles and come into contact with the plurality of first pads in the contacting, and the one or plurality of second pads have a surface hardness lower than a hardness of one or plurality of second inspection needles that are some of the plurality of inspection needles and come into contact with the one or plurality of second pads in the contacting

Further features of the present invention will become apparent from the following description of exemplary embodiments with reference to the attached drawings.

### BRIEF DESCRIPTION OF THE DRAWINGS

FIG. 1 is a diagram showing a semiconductor substrate according to a first embodiment;

FIG. 2 is a diagram showing the semiconductor substrate during electrical inspection according to the first embodiment;

FIG. 3 is a diagram showing a semiconductor substrate according to a first modified example;

FIG. 4 is a diagram showing a semiconductor substrate according to a second modified example;

FIG. 5 is a diagram showing a semiconductor substrate according to a third modified example; and

FIG. 6 is a diagram showing a semiconductor substrate according to a fourth modified example.

### DESCRIPTION OF THE EMBODIMENTS

Embodiments will be described below with reference to the drawings.

### First Embodiment

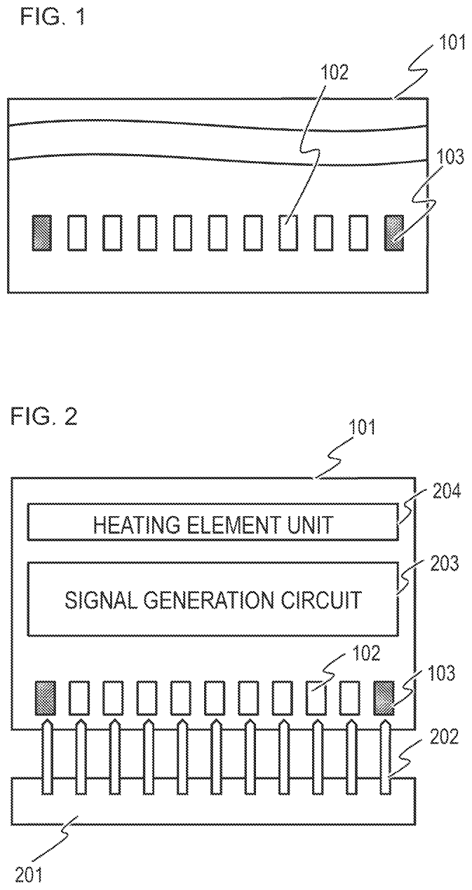

FIG. 1 is a diagram showing a configuration of a semiconductor substrate 101 according to a first embodiment. FIG. 1 shows a main surface (hereinafter referred to as a “lower surface”) of the semiconductor substrate 101 connected to an external substrate. A plurality of electrode pads 102 and a plurality of inspection pads 103 are disposed on the lower surface of the semiconductor substrate 101.

The electrode pads 102 are connected to internal circuits disposed inside the semiconductor substrate 101. The electrode pads 102 are pads to which signals from the external substrate are input or pads which output signals to the external substrate in a case in which the semiconductor substrate 101 is electrically connected to the external substrate. In the present embodiment, the plurality of electrode pads 102 form a one-dimensional array (aligned in one row) together with the plurality of inspection pads 103.

The inspection pads 103 are pads to which no signal is input from the external substrate and pads which do not output any signal to the external substrate. In addition, the inspection pads 103 are not connected to the internal circuits of the semiconductor substrate 101. Also, the inspection pads 103 are not connected to any active elements (transistors, diodes, operational amplifiers, etc.) or passive elements (resistors, capacitors, and coils).

The inspection pads 103 are disposed close to the electrode pads 102. In the present embodiment, one inspection pad 103 is disposed at each end of the plurality of electrode pads 102 in the one-dimensional array. At least one inspection pad 103 is a pad having a surface hardness lower than that of the electrode pads 102.

As a specific example of the semiconductor substrate 101, a case in which the semiconductor substrate 101 is a liquid discharge head substrate will be described with reference to FIG. 2. In this case, as the internal circuits, a signal generation circuit 203 and a heating element unit 204 are provided on the lower surface of the semiconductor substrate 101. The electrode pads 102 are electrically connected to the signal generation circuit 203 and the heating element unit 204. On the other hand, the inspection pads 103 are not electrically connected to the signal generation circuit 203 or the heating element unit 204.

The signal generation circuit 203 acquires electrical signals from the external substrate via the electrode pads 102 at a stage (a mounting stage) in which the semiconductor substrate 101 and the external substrate are electrically connected to each other. When the signal generation circuit 203 acquires the electrical signals, it generates ink discharge signals from the electrical signals. The signal generation circuit 203 outputs the generated ink discharge signals to the heating element unit 204.

When the heating element unit 204 acquires the ink discharge signals from the signal generation circuit 203, the heating element unit 204 discharges ink from a liquid discharge port of the heating element unit 204.

Also, as a method for electrically connecting the semiconductor substrate 101 to the external substrate, a bonding method such as wire bonding can be used.

Regarding Operation During Electrical Inspection

An operation of the semiconductor substrate 101 during electrical inspection and an electrical inspection method will be described below with reference to FIG. 2. In the electrical inspection, response signals are output from the semiconductor substrate 101 to an electrical inspection substrate 201 in response to electrical signals output from the electrical inspection substrate 201. In addition, on the basis of the output response signals, the electrical inspection substrate 201 detects whether or not the semiconductor substrate 101 is defective. Here, the electrical inspection is performed before the semiconductor substrate 101 is electrically connected to the external substrate by wire bonding. That is, the electrical inspection is performed at a stage in which the electrical inspection substrate 201 is prepared after the semiconductor substrate 101 shown in FIGS. 1 and 2 is prepared. A plurality of electrical inspection needles (probes) 202 are joined (connected) to the electrical inspection substrate 201.

First, in the electrical inspection, each electrode pad 102 and each inspection pad 103 are brought into contact with corresponding electrical inspection needles 202. Then, electrical signals supplied from the electrical inspection substrate 201 are output to the semiconductor substrate 101 via the electrode pads 102, and response signals from internal circuits of the semiconductor substrate 101 are output to the electrical inspection substrate 201 via the electrode pads 102. In this case, the inspection pads 103 do not input the electrical signals from the electrical inspection substrate 201 to the internal circuits and do not output the response signals.

Then, in the electrical inspection substrate 201, whether or not the semiconductor substrate 101 is defective is determined on the basis of whether or not the response signals output to the electrical inspection substrate 201 are within a preset allowable range (a range of signal levels). Specifically, if the response signals are within the preset allowable range, the semiconductor substrate 101 is determined to be non-defective (a non-defective substrate). On the other hand, if the response signals do not fall within the preset allowable range, the semiconductor substrate 101 is determined to be defective (a defective substrate).

Regarding Details of Each Pad and Electrical Inspection Needle

Detailed configurations of the electrode pads 102, the inspection pads 103, and the electrical inspection needles 202 will be described below.

Each of the electrode pads 102 is made (configured) of a material having a relatively high hardness (a hard material) such as tantalum, iridium, or an iridium alloy. Also, each of the inspection pads 103 having a surface hardness lower than that of the electrode pads 102 is made (configured) of a material having a low hardness (a soft material) such as aluminum or an alloy of aluminum and copper. Other inspection pads 103 are made of the same material as the electrode pads 102. Moreover, after both of the electrode pads 102 and the inspection pads 103 are made of tantalum, iridium, or an iridium alloy, only surface portions of the inspection pads 103 may be formed by plating with aluminum, an alloy of aluminum and copper, or the like.

As the electrical inspection needles 202, for example, inspection needles made of a relatively hard material such as tungsten or rhenium tungsten are used. For this reason, surface hardnesses of the electrode pads 102 are higher than hardnesses (surface hardnesses) of the electrical inspection needles 202 or equal to the hardnesses of the electrical inspection needles 202. Accordingly, the electrode pads 102 are less likely to leave needle marks generated by the contact of the electrical inspection needles 202. On the other hand, since the surface hardnesses of the inspection pads 103 are lower than the hardnesses of the electrical inspection needles 202, the needle marks generated by the contact of the electrical inspection needles 202 tend to remain on the inspection pads 103.

As described above, the needle marks generated when the electrical inspection needles 202 are brought into contact are hardly left on the electrode pads 102 having the high surface hardnesses. For this reason, even if outer shapes of the electrode pads 102 are observed after a defect of the semiconductor substrate 101 is detected in the electrical inspection, it is difficult to determine whether it is a defect due to an internal problem of the semiconductor substrate 101 or a contact failure between the electrical inspection needles 202 and the electrode pads 102.

On the other hand, if the electrical inspection needles 202 and the inspection pads 103 are in contact with each other during the electrical inspection, the needle marks remain on the inspection pads 103 having a low surface hardness. For this reason, by confirming the needle marks on the inspection pads 103 having a low surface hardness after a defect of the semiconductor substrate 101 is detected in the electrical inspection, a contact state between the electrical inspection needles 202 and the electrode pads 102 can be estimated. That is, it becomes easy to determine whether or not there is a contact failure between the electrical inspection needles 202 and the electrode pads 102.

Also, as a method for electrically connecting the semiconductor substrate 101 to an external substrate after electrical inspection, a bonding method such as a plating method for forming an Au layer (gold plating) on a pad surface is known. Since the electrode pads 102 having a high surface hardness are configured to have slippery pad surfaces, a bonding defect may occur when wire bonding is performed without forming an Au layer. On the other hand, since the Au layer is formed at a mounting stage (in a state in which the semiconductor substrate 101 and the external substrate are electrically connected to each other), reliability of the connection to the electrode pads 102 by wire bonding is improved. In addition, by forming the Au layer, it is possible to prevent ink from penetrating into the semiconductor substrate 101 through the electrode pads 102, and thus the reliability against ink penetration is improved.

Further, in the mounting stage, Au layers are formed on surfaces of the electrode pads 102 by plating, but the inspection pads 103 that are not used for wire bonding are not provided with Au layers by plating. For that reason, even if the needle marks are generated by the contact of the electrical inspection needles 202, there is no possibility of a defect (an adhesion defect) occurring during formation of the Au layers due to unevenness of the needle marks.

In addition, although one inspection pad 103 is disposed at each both end portions of the one-dimensional array in which the inspection pads 103 and the electrode pads 102 are arranged in one row, the present invention is not limited thereto, and only one inspection pad 103 may be disposed only at one end of the one-dimensional array. Also, in the one-dimensional array, the inspection pad 103 may be disposed between two electrode pads 102 among the plurality of electrode pads 102 (for example, at a center of the one-dimensional array). Alternatively, the inspection pads 103 may be disposed in a combination of these arrangements. In any case, the total number of inspection pads 103 not used for signal input and output may be smaller than the total number of electrode pads 102 used for signal input and output.

Also, in order to estimate the contact between the electrode pads 102 and the electrical inspection needles 202 from the needle marks left on the inspection pads 103, the inspection pads 103 and the electrode pads 102 are preferably close to each other. For this reason, in the one-dimensional array, an interval between the inspection pad 103 and the electrode pad 102 that are adjacent to each other may be narrower than twice an interval between two adjacent electrode pads 102. For example, the interval between the inspection pad 103 and the electrode pad 102 that are adjacent to each other may be substantially equal to (or may be the same as) the interval between the two adjacent electrode pads 102. In this case, since the inspection pads 103 can be formed in the same process as the electrode pads 102, the semiconductor substrate 101 can be formed more easily than in other cases.

As described above, by disposing the inspection pads 103, on which the needle marks are likely to be left, near the electrode pads 102, a user can determine to what extent the electrical inspection needles 202 are in contact with the electrode pads 102, on which the needle marks are less likely to be left. For this reason, the user can easily determine whether or not there is a contact failure between the electrode pads 102 and the electrical inspection needles 202.

Further, the electrical inspection can be performed normally without leaving the needle marks on the electrode pads 102 that are bonded to the external substrate. For this reason, in the electrode pads 102, it is possible to inhibit the possibility of occurrence of the adhesion defect caused by the unevenness of the needle marks at the time of bonding.

In addition, in the first embodiment, by differentiating the surface hardness of the inspection pads 103 from the surface hardness of the electrode pads 102, the needle marks are left on the inspection pads 103 without leaving the needle marks on the electrode pads 102. However, the surface hardness of the inspection pads 103 and the surface hardness of the electrode pads 102 may be the same as long as the needle marks can be left on the inspection pads 103 without leaving the needle marks on the electrode pads 102. In this case, for example, the hardness of the electrical inspection needles 202 in contact with the inspection pads 103 is made higher than the surface hardness of the inspection pads 103, and the hardness of the electrical inspection needles 202 in contact with the electrode pads 102 is made lower than the surface hardness of the electrode pads 102. That is, among the plurality of electrical inspection needles 202, the hardness of the needles that come into contact with the inspection pads 103 may be set higher than the hardness of the needles that come into contact with the electrode pads 102.

### First Modified Example

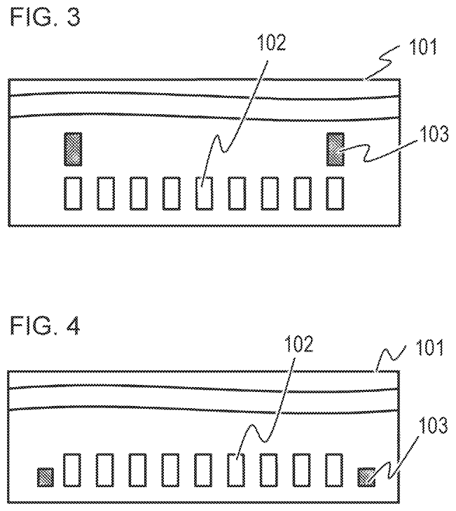

As shown in FIG. 3, the inspection pads 103 may not be disposed in the arrangement of the plurality of electrode pads 102 arranged in one row (one-dimensional array), but the inspection pads 103 may be disposed in a direction perpendicular to the row of the electrode pads 102. This makes it possible to narrow a width of the semiconductor substrate 101 (chip). Also, the inspection pads 103 may be disposed at any position as long as they are disposed close to the electrode pads 102. Further, it is not necessary that all the electrode pads 102 are arranged in a one-dimensional array, and at least some of the electrode pads 102 may be arranged in a one-dimensional array.

### Second Modified Example

As shown in FIG. 4, sizes of the inspection pads 103 (pad sizes) may be smaller than sizes of the electrode pads 102. Thus, it is possible to reduce a size of the semiconductor substrate 101.

### Third Modified Example

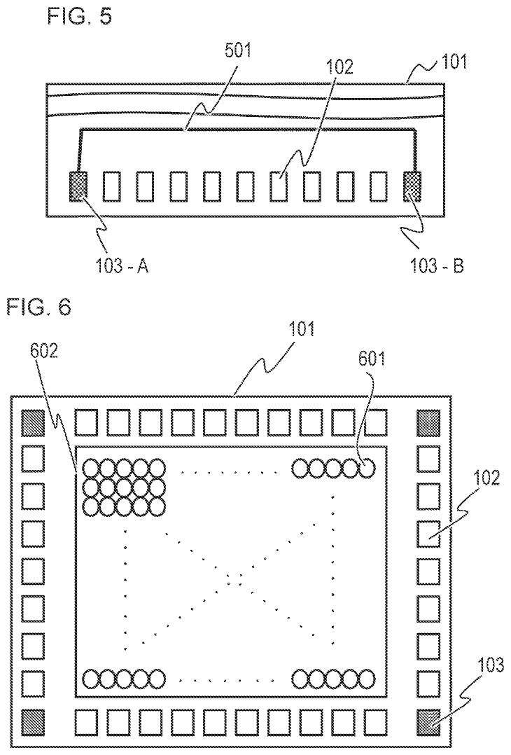

As shown in FIG. 5, the inspection pads 103-A and 103-B among the plurality of inspection pads 103 may be electrically directly connected (short-circuited) to each other by metal wiring 501. Although wire bonding for electrical connection with an external substrate is not performed on the inspection pads 103, in a third modified example, it is possible to check continuity using the inspection pads 103 during electrical inspection.

For example, during the electrical inspection, the electrical inspection needles 202 are brought into contact with the inspection pads 103-A and 103-B. In this case, when the electrical inspection needle 202 outputs a signal to the inspection pad 103-A, a signal can be output to the electrical inspection needle 202 from the inspection pad 103-B. Then, in a case in which the signal from the inspection pad 103-B is confirmed in the electrical inspection substrate 201, it can be confirmed that the electrical inspection needles 202 are normally in contact with the inspection pads 103 (and the electrode pads 102). On the other hand, in a case in which the signal from the inspection pad 103-B cannot be confirmed, it can be confirmed that a contact abnormality has occurred.

Thus, it is possible to determine whether or not there is a contact failure between the electrode pads 102 and the electrical inspection needles 202 in two stages, namely, confirmation of continuity using the inspection pads 103 and confirmation of the needle marks on the inspection pads 103 after the electrical inspection. That is, it is possible to determine the presence or absence of a contact failure between the electrode pads 102 and the electrical inspection needles 202 more accurately than in the first embodiment and the first and second modified examples.

### Fourth Modified Example

The semiconductor substrate 101 may be a solid-state imaging device. As shown in FIG. 6, a pixel region 602 in which pixels 601 are two-dimensionally arranged is disposed on a lower surface of the semiconductor substrate 101. The electrode pads 102 are disposed along four sides of the lower surface of the semiconductor substrate 101 to surround the pixel region 602. The inspection pads 103 are disposed at four corners of the lower surface of the semiconductor substrate 101.

In a fourth modified example, output signals are obtained by performing signal processing on signals obtained by photoelectrically converting optical signals from photodiodes included in the pixels 601. When these output signals are input to the electrode pads 102, the output signals are output from the electrode pads 102 to an external substrate.

Further, on each side of the lower surface of the semiconductor substrate 101, the inspection pads 103 are located at both end portions or at one end portion of the one-dimensional array in which the electrode pads 102 are arranged, or between any two electrode pads 102 in the one-dimensional array. Also, the inspection pads 103 may be disposed only at any of the four corners of the semiconductor substrate 101.

All of the above are merely specific examples for carrying out the present invention, and the technical scope of the present invention should not be construed to be limited by these. That is, the present invention can be embodied in various forms without departing from the technical concept or main features thereof.

According to the disclosure of the present technique, it is possible to prevent the needle marks from being left on specific pads on the semiconductor substrate during the electrical inspection, and to facilitate determination on what causes defects during the electrical inspection.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2021-184682, filed on Nov. 12, 2021, which is hereby incorporated by reference herein in its entirety.

What is claimed is:

1. A semiconductor substrate comprising:
an internal circuit;
a plurality of first pads electrically connected to the internal circuit; and
one or a plurality of second pads that have a surface hardness lower than that of the plurality of first pads and are not electrically connected to the internal circuit.

2. A semiconductor substrate electrically connected to an external substrate, the semiconductor substrate comprising:
an internal circuit that is a circuit to which a signal is input from the external substrate or a circuit that outputs a signal to the external substrate;
a plurality of first pads electrically connecting the internal circuit to the external substrate; and
one or a plurality of second pads that have a surface hardness lower than that of the plurality of first pads and do not electrically connect the internal circuit to the external substrate.

3. The semiconductor substrate according to claim 1, wherein at least some of the plurality of first pads form a one-dimensional array together with at least one of the one or plurality of second pads.

4. The semiconductor substrate according to claim 3, wherein at least one of the one or plurality of second pads is disposed at an end portion of the one-dimensional array.

5. The semiconductor substrate according to claim 3, wherein
the semiconductor substrate includes the plurality of second pads, and
any of the plurality of second pads is disposed at each of both end portions of the one-dimensional array.

6. The semiconductor substrate according to claim 3, wherein at least one of the one or plurality of second pads is disposed between two of the plurality of first pads.

7. The semiconductor substrate according to claim 3, wherein, in the one-dimensional array, an interval between the second pad and the first pad that are adjacent to each other are narrower than twice an interval between two first pads that are adjacent to each other.

8. The semiconductor substrate according to claim 7, wherein, in the one-dimensional array, the interval between the two first pads that are adjacent to each other and the interval between the second pad and the first pad that are adjacent to each other are substantially equal.

9. The semiconductor substrate according to claim 1, wherein the one or plurality of second pads are not connected to any passive element or active element.

10. The semiconductor substrate according to claim 1, wherein a number of the first pads is greater than a number of the one or plurality of second pads.

11. The semiconductor substrate according to claim 1, wherein
the semiconductor substrate includes the plurality of second pads, and
any two of the plurality of second pads are electrically connected to each other by wiring.

12. The semiconductor substrate according to claim 1, wherein a size of each of the one or plurality of second pads is smaller than a size of each of the plurality of first pads.

13. The semiconductor substrate according to claim 1, wherein
each of the plurality of first pads is made of tantalum, iridium, or an iridium alloy, and
each of the one or plurality of second pads is made of aluminum or an alloy of aluminum and copper.

14. The semiconductor substrate according to claim 1, further comprising a pixel region in which pixels are arranged two-dimensionally,
wherein the plurality of first pads are disposed to surround the pixel region.

15. The semiconductor substrate according to claim 1, wherein, in a state in which the semiconductor substrate is electrically connected to an external substrate, surfaces of the plurality of first pads are further plated with gold, and surfaces of the one or plurality of second pads are not plated with gold.

16. An electrical inspection method comprising:
preparing a semiconductor substrate including an internal circuit, a plurality of first pads electrically connected to the internal circuit, and one or a plurality of second pads not electrically connected to the internal circuit;
preparing an inspection substrate to which a plurality of inspection needles are connected; and
contacting the plurality of inspection needles with the plurality of first pads and the one or plurality of second pads, wherein
the plurality of first pads have a surface hardness higher than a hardness of a plurality of first inspection needles that are some of the plurality of inspection needles and come into contact with the plurality of first pads in the contacting, and
the one or plurality of second pads have a surface hardness lower than a hardness of one or plurality of second inspection needles that are some of the plurality of inspection needles and come into contact with the one or plurality of second pads in the contacting.

17. The electrical inspection method according to claim 16, wherein the plurality of first pads have a higher surface hardness than the one or plurality of second pads.

18. The electrical inspection method according to claim 16, wherein
each of the plurality of first pads is made of tantalum, iridium, or an iridium alloy,
each of the one or plurality of second pads is made of aluminum or an alloy of aluminum and copper, and
each of the plurality of inspection needles is made of tungsten.

19. The electrical inspection method according to claim 16, wherein the hardness of the one or plurality of second inspection needles that come into contact with the one or plurality of second pads in the contacting is higher than the hardness of the plurality of first inspection needles that come into contact with the plurality of first pads in the contacting.
